(19) United States
(12) Patent Application Publication
(10) Pub. No.: US 2013/0143363 A1
(43) Pub. Date: Jun. 6, 2013

(54) ADHESIVE COMPOSITION FOR SEMICONDUCTOR AND ADHESIVE FILM COMPRISING THE SAME

(71) Applicants: Sang Jin KIM, Uiwang-si (KR); Kyoung Tae WI, Uiwang-si (KR); Jae Won CHOI, Uiwang-si (KR); Sang Kyun KIM, Uiwang-si (KR); Cheol Su KIM, Uiwang-si (KR)

(72) Inventors: Sang Jin KIM, Uiwang-si (KR); Kyoung Tae WI, Uiwang-si (KR); Jae Won CHOI, Uiwang-si (KR); Sang Kyun KIM, Uiwang-si (KR); Cheol Su KIM, Uiwang-si (KR)

(21) Appl. No.: 13/705,594

(22) Filed: Dec. 5, 2012

(30) Foreign Application Priority Data
Dec. 6, 2011 (KR) 10-2011-0129522

(51) Int. Cl. C08L 63/00; H01L 21/56

(52) U.S. Cl. CPC C08L 63/00; H01L 21/56
USPC 438/118; 525/534; 525/523

(57) ABSTRACT

An adhesive film for a semiconductor may include about 60 wt % to about 80 wt % of a thermoplastic resin based on a total solid content of the adhesive film, a phenolic curing agent, and an amine curing agent, and the adhesive film may have a storage modulus of about 2 MPa or more and a reaction curing rate of about 50% or more when cured at 150° C. for 20 minutes.

### CROSS-REFERENCE TO RELATED APPLICATION

The present application claims priority under 35 U.S.C. §119 to Korean Patent Application No. 10-2011-0129522, filed on Dec. 6, 2011, in the Korean Intellectual Property Office, and entitled: “Adhesive Composition For Semiconductor and Adhesive Film Comprising the Same,” which is incorporated by reference herein in its entirety.

### BACKGROUND

Embodiments relate to an adhesive composition for a semiconductor and an adhesive film comprising the same.

### SUMMARY

Embodiments are directed to an adhesive film for a semiconductor, the adhesive film may include about 60 wt % to about 80 wt % of a thermoplastic resin based on a total solid content of the adhesive film, a phenolic curing agent, and an amine curing agent, and the adhesive film may have a storage modulus of about 2 MPa or more and a reaction curing rate of about 50% or more when cured at 150° C. for 20 minutes.

The adhesive film may have a void area ratio of about 10% or less when cured at 150° C. for 20 minutes and molded at 175° C. for 120 seconds.

The amine curing agent may include at least two amine groups.

The amine curing agent may include a compound represented by one of Formulae 1 to 5:

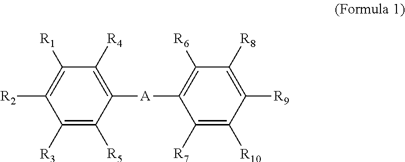

In Formula 1, A may be a single bond or may be selected from the group of —CH₂CH₂—, —SO₂—, —NHCO—, —C(CH₃)₂—, and —O—, and R₁ to R₁₀ may each independently selected be from the group of hydrogen, a C₁-C₄ alkyl group, a C₁-C₄ alkoxy group, and an amine group, with the proviso that at least one of R₁ to R₁₀ may be an amine group.

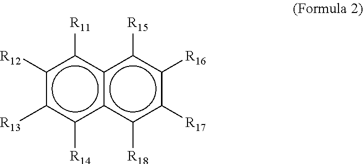

In Formula 2, R₁₁ to R₁₈ may each independently be selected from the group of hydrogen, a C₁ to C₄ alkyl group, an alkoxy group, a hydroxyl group, a cyanide group, a halogen, and an amine group, with the proviso that at least one of R₁₁ to R₁₈ may be an amine group.

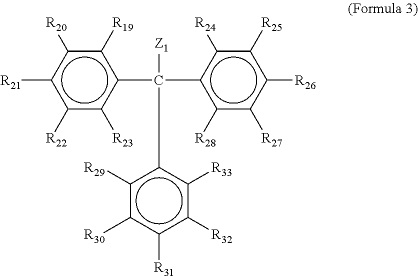

In Formula 3, Z₁ may be selected from the group of hydrogen, a C₁ to C₄ alkyl group, an alkoxy group, and a hydroxyl group, and R₁₉ to R₃₃ may each independently be selected from the group of hydrogen, a C₁ to C₄ alkyl group, an alkoxy group, a hydroxyl group, a cyanide group, a halogen, and an amine group, with the proviso that at least one of R₁₉ to R₃₃ may be an amine group.

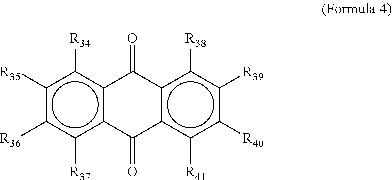

In Formula 4, R₃₄ to R₄₁ may each independently be selected from the group of hydrogen, a C₁ to C₄ alkyl group, an alkoxy group, a hydroxyl group, a cyanide group, a halogen, and an amine group, with the proviso that at least one of R₃₄ to R₄₁ may be an amine group.

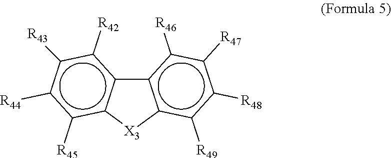

In Formula 5, X₃ may be selected from the group of —CH₂—, —NH—, —SO₂—, —S—, and —O—, and R₄₂ to R₄₉ may each independently be selected from the group of hydrogen, a C₁ to C₄ alkyl group, an alkoxy group, a hydroxyl group, a cyanide group, a halogen, and an amine group, with the proviso that at least one of R₄₂ to R₄₉ may be an amine group.

The amine curing agent may include the compound represented by Formula 1, at least one of R₁ to R₃ may be an amine group, and at least one of R₈ to R₁₀ may be an amine group.

R₂ and R₉ may each be an amine group.

The thermoplastic resin may have a weight average molecular weight of about 50,000 g/mol to about 5,000,000 g/mol.

The adhesive film may further include about 5 wt % to about 30 wt % of an epoxy resin, and the thermoplastic resin may be an epoxy group containing thermoplastic resin, and the epoxy resin and the thermoplastic resin may be different.

The weight ratio of the phenolic curing agent to the amine curing agent may range from about 3:1 to about 1:11.

The adhesive film may further include a curing catalyst.

The curing catalyst may have a melting point of about 100° C. to about 160° C.

The curing catalyst may include at least one selected from the group of a melamine catalyst, an imidazole catalyst, and a phosphorous catalyst.

The adhesive film may further include a silane coupling agent.

Embodiments are also directed toward an adhesive composition for a semiconductor, the adhesive composition may include about 60 wt % to about 80 wt % of a thermoplastic resin, about 5 wt % to about 30 wt % of an epoxy resin, about 0.5 wt % to about 14 wt % of a phenolic curing agent, about 1 wt % to about 10 wt % of an aromatic diamine curing agent, about 0.1 wt % to about 10 wt % of a curing catalyst, about 0.14 wt % to about 5 wt % of a silane coupling agent, and about 1 wt % to about 30 wt % of a filler, based on a total amount of the adhesive composition in terms of solid content.

The adhesive composition may have a storage modulus of about 2 MPa or more and a reaction curing rate of about 50% or more when cured at 150° C. for 20 minutes.

Embodiments are also directed toward a method of manufacturing a semiconductor device, the method may include attaching a first chip to a substrate using an adhesive film, wire bonding the first chip to the substrate, and epoxy-mold curing the wire bonded first chip and substrate, and the adhesive film may include about 60 wt % to about 80 wt % of a thermoplastic resin based on a total solid content of the adhesive film, a phenolic curing agent, and an amine curing agent, and the adhesive film may have a storage modulus of about 2 MPa or more and a reaction curing rate of about 50% or more when cured at 150° C. for 20 minutes.

The substrate may be a wiring substrate or a second chip.

The wire bonding may be successively performed after attaching the first chip to the substrate.

The adhesive film may be completely cured during the epoxy-mold curing.

Attaching the first chip to the substrate may be performed at about 100° C. to about 150° C. for about 1 minute to about 10 minutes, wire bonding the first chip to the substrate may be performed at about 140° C. to about 160° C. for about 10 minutes to about 30 minutes, and epoxy-mold curing the wire bonded first chip and substrate may be performed at about 170° C. to about 180° C. for less than about 5 minutes.

### BRIEF DESCRIPTION OF THE DRAWING

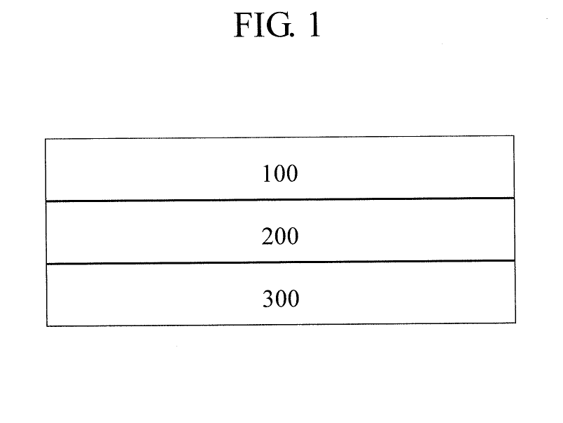

Features will become apparent to those of skill in the art by describing in detail exemplary embodiments with reference to the attached drawing in which FIG. 1 illustrates a semiconductor device according to an embodiment.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figure, the dimensions of layers and regions may be exaggerated for clarity of illustration. Like reference numerals refer to like elements throughout.

Unless otherwise specified, the amount of each component will be referred to in terms of solid content throughout the specification.

In an embodiment, an adhesive film may include 60 wt % to 80 wt % of a thermoplastic resin based on the total solid content of the adhesive film, a phenolic curing agent, and an amine curing agent, and the adhesive film may have a storage modulus of about 2 MPa or more and a reaction curing rate of about 50% or more after curing at 150° C. for 20 minutes.

The composition may include 60 wt % to 80 wt % of the thermoplastic resin, and thus it may achieve effective removal of voids upon epoxy-mold curing (EMC) molding (when the voids are generated in a printed circuit board (PCB) during a die-attach process). When the amount of the thermoplastic resin is within the above range, the voids generated during the die-attach process may be substantially removed upon EMC molding.

The adhesive composition for semiconductors may include both the phenolic curing agent and the amine curing agent. For example, the adhesive composition may include the phenolic curing agent along with the epoxy resin and the amine curing agent. Thus, the adhesive composition may form an improved crosslinking structure, e.g., through acid promotion of the phenolic curing agent even with reduced thermal exposure in a die-attach process (e.g., at 120° C. for several minutes) and a wire bonding process (e.g., at 150° C. for about 20 minutes). Accordingly, reliability deterioration resulting from failure and/or insufficient adhesion (e.g., caused by foaming of the composition due to insufficient curing) may be substantially prevented.

A suitable phenolic curing agent may be used, for example, bisphenol resins, (which contain two or more phenolic hydroxyl groups in a single molecule and may exhibit improved electrolytic corrosion resistance upon hydrolysis) such as bisphenol A, bisphenol F, bisphenol S, and the like; phenol novolac resins; bisphenol A novolac resins; and phenolic resins such as xylene, cresol novolac, biphenyl resins, and the like, and combinations thereof, may be used.

The amine curing agent for use in the adhesive composition may be an aromatic diamine curing agent, and thus may provide substantially improved curing rate adjustment. For example, the amine curing agent may be an amine compound selected from compounds represented by one of the following Formulae 1 to 5.

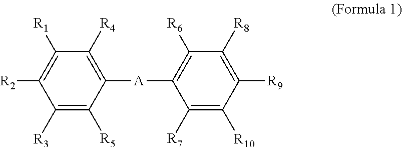

In Formula 1, A may be a single bond or may be selected from the group of —CH₂CH₂—, —SO₂—, —NHCO—, —C(CH₃)₂—, and —O—. R₁ to R₁₀ may each independently be selected from the group of hydrogen, a C₁-C₄ alkyl group, a C₁-C₄ alkoxy group, and an amine group. In an implementation, at least one of R₁ to R₁₀ is an amine group.

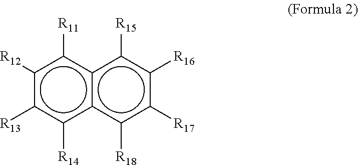

In Formula 2, R₁₁ to R₁₈ may each independently be selected from the group of hydrogen, a C₁ to C₄ alkyl group, an alkoxy group, a hydroxyl group, a cyanide group, a halogen, and an amine group. In an implementation, at least one of R₁₁ to R₁₈ is an amine group.

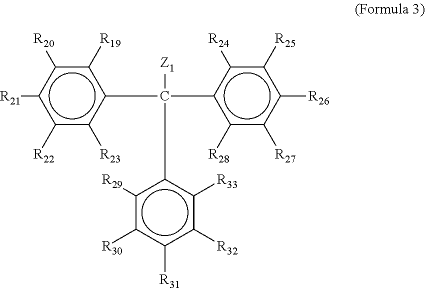

In Formula 3, Z₁ may be selected from the group of hydrogen, a C₁ to C₄ alkyl group, an alkoxy group, and a hydroxyl group. R₁₉ to R₃₃ may each independently be selected from the group of hydrogen, a C₁ to C₄ alkyl group, an alkoxy group, a hydroxyl group, a cyanide group, a halogen, and an amine group. In an implementation, at least one of R₁₉ to R₃₃ is an amine group.

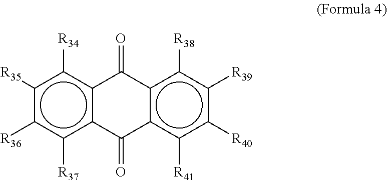

In Formula 4, R₃₄ to R₄₁ may each independently be selected from the group of hydrogen, a C₁ to C₄ alkyl group, an alkoxy group, a hydroxyl group, a cyanide group, a halogen, and an amine group. In an implementation, at least one of R₃₄ to R₄₁ is an amine group.

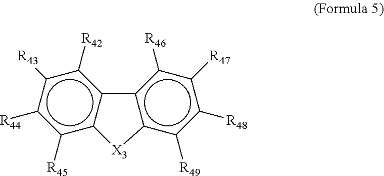

In Formula 5, X₃ may be selected from the group of —CH₂—, —NH—, —SO₂—, —S—, and —O—. R₄₂ to R₄₉ may each independently be selected from the group of hydrogen, a C₁ to C₄ alkyl group, an alkoxy group, a hydroxyl group, a cyanide group, a halogen, and an amine group. In an implementation, at least one of R₄₂ to R₄₉ is an amine group.

The weight ratio of the phenolic curing agent to the amine curing agent may range from 3:1 to 1:11, for example from 2:1 to 1:5. The

The adhesive film may have a storage modulus of about 2 MPa or more and a reaction curing rate of about 50% or more when cured at 150° C. for 20 minutes. The storage modulus of about 2 MPa or more and reaction curing rate of about 50% or more when cured at 150° C. for 20 minutes (which may be conditions simulating temperature and reaction time of the wire bonding process) may be characteristics that indicate that the adhesive film may form a improved crosslinking structure through rapid curing even with reduced thermal exposure, thereby substantially preventing reliability deterioration resulting from failure and insufficient adhesion (e.g., caused by foaming of the adhesive film due to insufficient curing).

In this disclosure, the term “storage modulus” refers to storage modulus of an adhesive film coated as an adhesive composition, as measured using a dynamic mechanical analyzer (DMA) at 150° C. when heated from 30° C. to 260° C. at a temperature increasing rate of 4° C./min after curing at 150° C. for 20 minutes. The ratio of components of the adhesive composition including the thermoplastic resin, the epoxy resin, the curing agents, and the like, may result in the adhesive film having a storage modulus at 150° C. from about 2 MPa to about 10 MPa after curing at 150° C. for 20 minutes.

In this disclosure, the reaction curing rate of the adhesive film is calculated according to the following equation. In this equation, the heat quantity before curing may be measured using differential scanning calorimetry (DSC) by scanning the adhesive film specimen coated as an adhesive composition at a temperature increasing rate of 10° C./min from 0 to 300° C., and the post-curing heat quantity may be measured after curing on a hot plate at 150° C. for 20 minutes.

Reaction curing rate (%)=(1-(post-curing heat quantity)/(pre-curing heat quantity))*100%

The adhesive film may have a void area ratio of about 10% or less when cured at 150° C. for 20 minutes and molded at 175° C. for 120 seconds, for example about 7% or less, or about 5% or less. To measure the void area ratio, a chip (adhesive+chip) (10 mm×10 mm), which is provided at one side thereof with the adhesive film, is attached to a pretreated PCB at 120° C. under a load of 1 kgf for 1 second, and cured on a hot plate at 150° C. for 20 minutes, followed by EMC molding at 175° C. for 120 seconds. Then, an adhesive layer of the molded sample is exposed and photographed using a microscope (magnification of 25×) to inspect for the presence of voids through image analysis. To count the number of voids, a lattice counting method is used. Specifically, the overall area is divided into 10 lattices in a longitudinal direction and 10 lattices in a transverse direction, and the number of lattices including a void is counted and converted into a percentage (%) (void area ratio).

Void area ratio=(void area/total area)×100%

The adhesive composition or film may be advantageously used as an adhesive for a die-to-printed circuit board.

The adhesive composition or film may further include a curing catalyst. The curing catalyst may have a melting point of about 100° C. to about 160° C. The curing catalyst may be at least one selected from the group of melamine, imidazole, and phosphorus catalysts.

The adhesive composition or film may further include a silane coupling agent.

The adhesive composition may include about 60 wt % to about 80 wt % of a thermoplastic resin, about 5 wt % to about 30 wt % of an epoxy resin, about 0.5 wt % to about 14 wt % of a phenolic curing agent, about 1 wt % to about 10 wt % of an amine curing agent, about 0.1 wt % to about 10 wt % of a curing catalyst, about 0.14 wt % to about 5 wt % of a silane coupling agent, and about 1 wt % to about 30 wt % of a filler, based on the total amount of the composition in terms of solid content.

The weight ratio of the thermoplastic resin (A) to a curing system, which may include the epoxy resin (B), the phenolic curing agent (C) and the amine curing agent (D), that is, (A):((B)+(C)+(D)), may range from about 60 to 80: 6.5 to 54 (i.e., about 60:54 to about 80:6.5).

In an embodiment, a method of manufacturing a semiconductor device may include attaching a chip to substrate (e.g., a wiring substrate) or attaching chips to each other using the adhesive film, wire bonding the chips or the wiring substrate; and epoxy-mold curing the wire bonded wiring substrate or chips. The adhesive film may include about 60 wt % to about 80 wt % of a thermoplastic resin based on the total solid content of the adhesive film, a phenolic curing agent, and an amine curing agent, and the adhesive film may have a storage modulus of about 2 MPa or more and a reaction curing rate of about 50% or more after curing at 150° C. for 20 minutes. Wire bonding may be successively performed after the attachment process. Upon epoxy-mold curing, the adhesive film may be completely cured. In an embodiment, the attachment may be performed at about 100° C. to about 150° C. for about 1 to about 10 minutes with reference to a PCB strip, the wire bonding may be performed at about 140° C. to about 160° C. for about 10 to about 30 minutes, and the epoxy mold-curing may be performed at about 170° C. to about 180° C. for about 1 to about 5 minutes.

For example, the attachment may be performed at 120° C. for about 5 minutes, the wire bonding may be performed at 150° C. for 20 minutes, and the epoxy-mold curing may be performed at 175° C. for about 2 minutes.

The epoxy-mold curing may be performed for a reduced reaction time. For example, the epoxy-mold curing may be performed at 175° C. for 2 minutes or less, for example for 1 minutes or less.

FIG. 1 illustrates, by way of example, the chip 100 attached to the substrate (e.g., a wiring substrate or another chip) 300 by using the adhesive film 200.

Each component described above for the adhesive composition (i.e., the thermoplastic resin, epoxy resin, phenolic curing resin, amine curing resin, and the curing catalyst) will be described below in greater detail.

Thermoplastic Resin

Examples of thermoplastic resins for use in the adhesive composition may include polyimide resins, polystyrene resins, polyethylene resins, polyester resins, polyamide resins, butadiene rubbers, acryl rubbers, (meth)acrylate resins, urethane resins, polyphenylene ether resins, polyether imide resins, phenoxy resins, polycarbonate resins, modified polyphenylene ether resins, and the like, and mixtures thereof. For example, the thermoplastic resin may contain an epoxy group. In an implementation, an epoxy group containing (meth)acrylic copolymer may be used as the thermoplastic resin.

The thermoplastic resin may have a glass transition temperature of about −30° C. to about 80° C., for example about 5° C. to about 60° C., or about 5° C. to about 35° C. Within this range, the composition may provide improved flowability and may exhibit improved void removing capability, and may provide improved adhesion and reliability.

In an embodiment, the thermoplastic resin may have a weight average molecular weight of about 50,000 g/mol to about 5,000,000 g/mol.

The thermoplastic resin may be present in an amount of about 60 wt % to about 80 wt %, based on the total amount of the composition in terms of solid content. Within this range, effective removal of voids may be facilitated during EMC molding (when the voids are generated in a PCB during the die-attach process). When the amount of the thermoplastic resin is within the above range, the voids generated during the die-attach process may be substantially removed.

Further, the weight ratio of the thermoplastic resin (A) to a mixture of the epoxy resin (B), phenolic curing agent (C), and amine curing agent (D), that is, (A) : ((B)+(C)+(D)), may range from about 60 to 80: 6.5 to 54 (i.e., about 60:54 to about 80:6.5). Within this range, void generation may be advantageously suppressed.

Epoxy Resin

The epoxy resin may be curable and may impart adhesion to the composition. The epoxy resin may be a liquid epoxy resin, a solid epoxy resin, or a mixture thereof.

Examples of liquid epoxy resins include bisphenol A type liquid epoxy resins, bisphenol F type liquid epoxy resins, tri- or more polyfunctional liquid epoxy resins, rubber-modified liquid epoxy resins, urethane-modified liquid epoxy resins, acrylic modified liquid epoxy resins, photosensitive liquid epoxy resins, and the like. These liquid epoxy resins may be used alone or as a mixture thereof For example, a bisphenol A type liquid epoxy resin may be used.

The liquid epoxy resin may have an epoxy equivalent weight of about 100 g/eq. to about 1,500 g/eq, for example from about 150 g/eq. to about 800 g/eq., or from about 150 g/eq. to about 400 g/eq. Within this range, a cured product with improved adhesion and heat resistance may be obtained while maintaining the glass transition temperature.

The liquid epoxy resin may have a weight average molecular weight ranging from about 100 g/mol to about 1,000 g/mol. This range may be advantageous in terms of increased flowability.

The solid epoxy resin may be one that is a solid or quasi-solid at room temperature and may have one or more functional groups. The solid epoxy resin may have a softening point (Sp) of about 30° C. to about 100° C. Examples of suitable solid epoxy resins may include bisphenol epoxy resins, phenol novolac epoxy resins, o-cresol novolac epoxy resins, polyfunctional epoxy resins, amine epoxy resins, heterocyclic epoxy resins, substituted epoxy resins, naphthol-based epoxy resins, biphenyl-based epoxy resins, and the like, and derivatives thereof

Commercially available solid epoxy resins may include the following. Examples of bisphenol epoxy resins may include YD-017H, YD-020, YD020-L, YD-014, YD-014ER, YD-013K, YD-019K, YD-019, YD-017R, YD-017, YD-012, YD-011H, YD-011S, YD-011, YDF-2004, YDF-2001 (Kukdo Chemical Co., Ltd.), etc. Examples of phenol novolac epoxy resins may include EPIKOTE 152 and EPIKOTE 154 (Yuka Shell Epoxy Co., Ltd.); EPPN-201 (Nippon Kayaku Co., Ltd.); DN-483 (Dow Chemical Company); YDPN-641, YDPN-638A80, YDPN-638, YDPN-637, YDPN-644, YDPN-631 (Kukdo Chemical Co., Ltd.), etc. Examples of o-cresol novolac epoxy resins may include: YDCN-500-1P, YDCN-500-2P, YDCN-500-4P, YDCN-500-5P, YDCN-500-7P, YDCN-500-8P, YDCN-500-10P, YDCN-500-80P, YDCN-500-80PCA60, YDCN-500-80PBC60, YDCN-500-90P, YDCN-500-90PA75 (Kukdo Chemical Co., Ltd.); EOCN-102S, EOCN-1035, EOCN-104S, EOCN-1012, EOCN-1025, EOCN-1027 (Nippon Kayaku Co., Ltd.); YDCN-701, YDCN-702, YDCN-703, YDCN-704 (Tohto Kagaku Co., Ltd.); Epiclon N-665-EXP (Dainippon Ink and Chemicals, Inc.), etc. Examples of bisphenol novolac epoxy resins may include KBPN-110, KBPN-120, KBPN-115 (Kukdo Chemical Co., Ltd.), etc. Examples of polyfunctional epoxy resins may include Epon 1031S (Yuka Shell Epoxy Co., Ltd.); Araldite 0163 (Ciba Specialty Chemicals); Detachol EX-611, Detachol EX-614, Detachol EX-614B, Detachol EX-622, Detachol EX-512, Detachol EX-521, Detachol EX-421, Detachol EX-411, Detachol EX-321 (NAGA Celsius Temperature Kasei Co., Ltd.); EP-5200R, KD-1012, EP-5100R, KD-1011, KDT-4400A70, KDT-4400, YH-434L, YH-434, YH-300 (Kukdo Chemical Co., Ltd.), etc. Examples of amine epoxy resins may include EPIKOTE 604 (Yuka Shell Epoxy Co., Ltd.); YH-434 (Tohto Kagaku Co., Ltd.); TETRAD-X and TETRAD-C (Mitsubishi Gas Chemical Company Inc.); ELM-120 (Sumitomo Chemical Industry Co., Ltd.), etc. Examples of heterocyclic epoxy resins may include PT-810 (Ciba Specialty Chemicals). Examples of substituted epoxy resins may include: ERL-4234, ERL-4299, ERL-4221, ERL-4206 (UCC Co., Ltd.), etc. Examples of naphthol epoxy resins may include: Epiclon HP-4032, Epiclon HP-4032D, Epiclon HP-4700, and Epiclon HP-4701 (Dainippon Ink and Chemicals, Inc.). Examples of non-phenolic epoxy resins may include YX-4000H (Japan Epoxy Resin), YSLV-120TE, GK-3207 (Nippon steel chemical), NC-3000 (Nippon Kayaku), etc. These epoxy resins may be used alone or as mixtures.

The epoxy resin may be present in an amount of about 5 wt % to about 30 wt %, for example about 7 wt % to about 20 wt %, based on the total solid content of the adhesive composition. Within this range, improved reliability and improved mechanical properties may be attained.

Curing Agent

The curing agent may include two types of curing agents having different reaction temperature zones.

In an embodiment, the curing agent may include a phenolic curing agent and an amine curing agent.

The phenolic curing agent may be a suitable phenolic curing agent, for example, bisphenol resins (which include two or more phenolic hydroxyl groups in a single molecule and exhibit excellent electrolytic corrosion resistance upon hydrolysis), such as bisphenol A, bisphenol F, bisphenol S, and the like; phenol novolac resins; bisphenol A novolac resins; and phenolic resins such as xylene, cresol novolac, biphenyl resins, and the like. For example, phenol novolac resins or bisphenol A novolac resins may be used.

Examples of commercially available phenolic curing agents may include H-1, H-4, HF-1M, HF-3M, HF-4M, and HF-45 (Meiwa Plastic Industries Co., Ltd.); examples of paraxylene phenolic curing agents may include MEH-78004S, MEH-7800SS, MEH-7800S, MEH-7800M, MEH-7800H, MEH-7800HH, and MEH-78003H (Meiwa Plastic Industries Co., Ltd.), PH-F3065 (Kolong Industries Co., Ltd.); examples of biphenyl curing agents may include MEH-7851SS, MEH-7851S, MEH-7851M, MEH-7851H, MEH-78513H, MEH-78514H (Meiwa Plastic Industries Co., Ltd.), and KPH-F4500 (Kolong Industries Co., Ltd.); and examples of triphenylmethyl curing agents may include MEH-7500, MEH-75003S, MEH-7500SS, MEH-7500S, MEH-7500H (Meiwa Plastic Industries Co., Ltd.), etc. These may be used alone or as mixtures thereof The phenolic curing agent may be present in an amount of about 0.5 wt % to about 14 wt %, for example about 1 wt % to about 10 wt %, based on the total solid content of the adhesive composition.

The amine curing agent for use in the adhesive composition may be an aromatic diamine curing agent, and thus may provide substantially improved curing rate adjustment. For example, the amine curing agent may be an aromatic compound having two or more amine groups in a single molecule. In an implementation, the amine curing resin may be represented by, for example, one of Formulae 1 to 5.

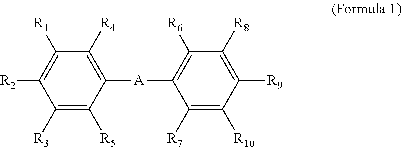

In Formula 1, A may be a single bond or may be selected from the group of —CH₂—, —CH₂CH₂—, —SO₂—, —NHCO—, —C(CH₃)₂—, and —O—. R₁ to R₁₀ may each independently be selected from the group of hydrogen, a C₁-C₄ alkyl group, a C₁-C₄ alkoxy group, and an amine group. In an implementation, at least one of R₁ to R₁₀ is an amine group.

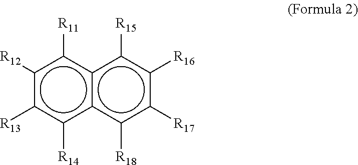

In Formula 2, R₁₁ to R₁₈ may each independently be selected from the group of hydrogen, a C₁ to C₄ alkyl group, an alkoxy group, a hydroxyl group, a cyanide group, a halogen, and an amine group. In an implementation, at least one of R₁₁ to R₁₈ is an amine group.

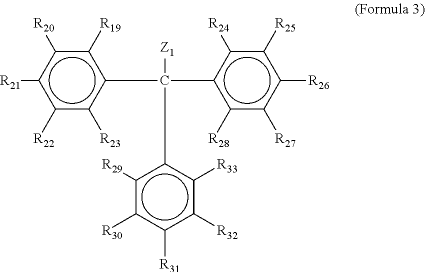

In Formula 3, Z₁ may be selected from the group of hydrogen, a C₁ to C₄ alkyl group, an alkoxy group, and a hydroxyl group. R₁₉ to R₃₃ may each independently be selected from the group of hydrogen, a C₁ to C₄ alkyl group, an alkoxy group, a hydroxyl group, a cyanide group, a halogen, and an amine group. In an implementation, at least one of R₁₉ to R₃₃ is an amine group.

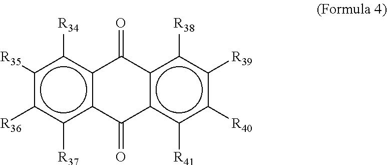

In Formula 4, R₃₄ to R₄₁ may each independently be selected from the group of hydrogen, a C₁ to C₄ alkyl group, an alkoxy group, a hydroxyl group, a cyanide group, a halogen, and an amine group. In an implementation, at least one of R₃₄ to R₄₁ is an amine group.

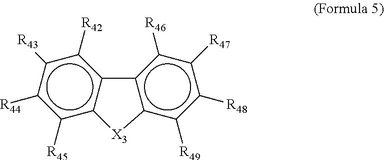

In Formula 5, X₃ may be selected from the group of —CH₂—, —NH—, —SO₂—, —S—, and —O—. R₄₂ to R₄₉ may each independently be selected from the group of hydrogen, a C₁ to C₄ alkyl group, an alkoxy group, a hydroxyl group, a cyanide group, a halogen, and an amine group. In an implementation, at least one of R₄₂ to R₄₉ is an amine group.

Example of the curing agent represented by Formula 1 may include 3,3′-diaminobenzidine, 4,4′-diaminodiphenyl methane, 4,4′ or 3,3′-diaminodiphenyl sulfone, 4,4′-diaminobenzophenon, 4,4′-diaminodiphenyl ether, 3,3′-diaminobenzophenon, 1,4′ or 1,3′-bis(4 or 3-aminocumyl)benzene, 1,4′bis(4 or 3-aminophenoxy)benzene, 2,2′-bis[4-(4 or 3-aminophenoxy)phenyl]propane, bis[4-(4 or 3-aminophenoxy)phenyl]sulfone, 4,4′-diamino-3,3′,5,5′-tetrabutyldiphenylketone, 4,4′-diamino-3,3′,5,5′-tetraethyldiphenylketone, 4,4′-diamino-3,3′,5,5′-tetra-n-propylenediphenylketone, 4,4′-diamino-3,3′,5,5′-tetraisopropyldiphenylketone, 4,4′-diamino-3,3′,5,5′-tetramethyldiphenylketone, 4,4′-diamino-3,3′,5,5′-tetra-n-propyldiphenylmethane, 4,4′-diamino-3,3′5,5-tetramethyldiphenylmethane, 4,4′-diamino-3,3′5,5′-tetraisopropyldiphenylmethane, 4,4′-diamino-3,3′5,5′-tetraethyldiphenylmethane, 4,4′-diamino-3,3′-dimethyl-5,5′-diethyldiphenylmethane, 4,4′-diamino-3,3′-dimethyl-5,5′-diisopropyldiphenylmethane, 4,4′-diamino-3,3′-diethyl-5,5′-diethyldiphenylmethane, 4,4′-diamino-3,5′-dimethyl-3′,5′-diethyldiphenylmethane, 4,4′-diamino-3,5-dimethyl-3′,5′-diisopropyldiphenylmethane, 4,4′-diamino-3,5-diethyl-3′,5′-dibutyldiphenylmethane, 4,4′-diamino-3,5-diisopropyl-3′,5′-dibutyldiphenylmethane, 4,4′-diamino-3,3′-diisopropyl-5,5′-dibutyldiphenylmethane, 4,4′-diamino-3,3′-dimethyl-5′,5′-dibutyldiphenylmethane, 4,4′-diamino-3,3′-diethyl-5′,5′-dibutyldiphenylmethane, 4,4′-diamino-3,3′-dimethyldiphenylmethane, 4,4′-diamino-3,3′-diethyldiphenylmethane, 4,4′-diamino-3,3′-di-n-propyldiphenylmethane, 4,4′-diamino-3,3′-diisopropyldiphenylmethane, 4,4′-diamino-3,3′-dibutyldiphenylmethane, 4,4′-diamino-3,3′,5-trimethyldiphenylmethane, 4,4′-diamino-3,3′,5-triethyldiphenylmethane, 4,4′-diamino-3,3′,5-tri-n-propyldiphenylmethane, 4,4′-diamino-3,3′,5-triisopropyldiphenylmethane, 4,4′-diamino-3,3′,5-tributyldiphenylmethane, 4,4′-diamino-3-methyl-3′-ethyldiphenylmethane, 4,4′-diamino-3-methyl-3′-isopropyldiphenylmethane, 4,4′-diamino-3-methyl-3′-butyldiphenylmethane, 4,4′-diamino-3-isopropyl-3′-butyldiphenylmethane, 2,2-bis(4-amino-3,5-dimethylphenyl)propane, 2,2-bis(4-amino-3,5-diethylphenyl)propane, 2,2-bis(4-amino-3,5-di-n-propylphenyl)propane, 2,2-bis(4-amino-3,5-diisopropylphenyl)propane, 2,2-bis(4-amino-3,5- dibutylphenyl)propane, 4,4′-diamino-3,3′,5,5′-tetramethyldiphenylbenzanilide, 4,4′-diamino-3,3′,5,5′-tetraethyldiphenylbenzanilide , 4,4′-diamino-3,3′,5,5′-tetra-n-propyldiphenylbenzanilide, 4,4′-diamino-3,3′,5,5′-tetraisopropyldiphenylbenzanilide, 4,4′-diamino-3,3′,5,5′-tetrabutyldiphenylbenzanilide, 4,4′-diamino-3,3′,5,5′-tetramethyldiphenylsulfone, 4,4′-diamino-3,3′,5,5′-tetraethyldiphenylsulfone, 4,4′-diamino-3,3′,5,5′-tetra-n-propyldiphenylsulfone, 4,4′-diamino-3,3′,5,5′-tetraisopropyldiphenylsulfone, 4,4′-diamino-3,3′,5,5′-tetramethyldiphenylether, 4,4′-diamino-3,3′,5,5′-tetraethyldiphenylether, 4,4′-diamino-3,3′,5,5′-tetra-n-propyldiphenylether, 4,4′-diamino-3,3′,5,5′-tetraisopropyldiphenylether, 4,4′-diamino-3,3′,5,5′-tetrabutyldiphenylether, 3,3′-diaminobenzophenon, 3,4-diaminobenzophenon, 3,3′-diaminodiphenylether, 3,3′-diaminodiphenylmethane, 3,4′-diaminodiphenylmethane, 2,2′-diamino-1,2-diphenylethane or 4,4′-diamino-1,2-diphenylethane, 2,4-diaminodiphenylamine, 4,4′-diaminooctafluorobiphenyl, o-dianisidine, and the like.

Examples of the curing agent represented by Formula 2 may include 1,5-diaminonaphthalene, 1,8-diaminonaphthalene, 2,3-diaminonaphthalene, and the like.

Examples of the curing agent represented by Formula 3 may include pararosaniline and the like.

Examples of the curing agent represented by Formula 4 may include 1,2-diaminoanthraquinone, 1,4-diaminoanthraquinone, 1,5-diaminoanthraquinone, 2,6-diaminoanthraquinone, 1,4-diamino-2,3-dichloroanthraquinone, 1,4-diamino-2,3-dicyano-9,10-anthraquinone, 1,4-diamino-4,8-dihydroxy-9,10-anthraquinone, and the like.

Examples of the curing agent represented by Formula 5 may include 3,7-diamino-2,8-dimethyldibenzothiophenesulfone, 2,7-diaminofluorene, 3,6-diaminocarbazole, and the like.

Further, the curing agents such as paraphenylene diamine, metaphenylene diamine, metatoluene diamine, 2,2′-bis[4-(4 or 3-aminophenoxy)phenyl]hexafluorosulfone, 2,2′-bis[4-(4 or 3-aminophenoxy)phenyl]hexafluoropropane other than the above curing agent may be used in the present invention.

The amine curing resin may be present in an amount of about 1 wt % to about 10 wt %, for example about 1 wt % to about 5 wt %, based on the total solid content of the adhesive composition.

Curing Catalyst

The adhesive composition may further include a curing catalyst. The curing catalyst may help promote curing of the epoxy resin during the semiconductor process.

The curing catalyst may be at least one selected from the group of melamine, imidazole, and phosphorous catalysts. For example, a phosphorous catalyst may be used.

Examples of phosphorous catalysts for use in the adhesive composition may include phosphine curing catalysts, such as, TBP, TMTP, TPTP, TPAP, TPPO, DPPE, DPPP, DPPB (Hokko Chemical Industry Co., Ltd.), and the like.

Examples of imidazole curing catalysts for use in the adhesive composition may include 2-methylimidazole, 2-ethyl-4-methylimidazole, 2-undecylimidazole, 2-heptadecylimidazole, 2-phenylimidazole, 2-phenyl-4-methylimidazole, 1-benzyl-2-methylimidazole, 2-ethylimidazole, 2-isopropylimidazole, 2-phenyl-4-benzylimidazole, 2-phenyl-4,5 -dihydroxymethylimidazole, 2-phenyl-4-methyl-5-hydroxymethylimidazole, 2-phenyl-4-benzyl-5-hydroxymethylimidazole, 4-4′-methylenebis-(2-ethyl-5-methylimidazole), 2-aminoethyl-2-methylimidazole, 1-cyanoethyl-2-phenyl-4,5-di(cyanoethoxymethyl)imidazole, and the like. Examples of commercially available imidazole curing catalysts include 2MZ, 2E4MZ, C11Z, C17Z, 2PZ, 2PZ-CN, 2P4MZ, 1B2MZ, 2EZ, 2IZ, 2P4BZ, 2PH2-PW, 2P4MHZ, 2P4BHZ, 2E4MZ-BIS, AMZ, 2PHZ-CN (Asahi Kasei Corporation). For example, as the imidazole curing catalyst, 2-phenyl-4,5-dihydroxymethylimidazole or 2-phenyl-4-methylimidazole may be used.

The curing catalyst may be present in an amount of about 0.1 wt % to about 10 wt % based on the total solid content of the adhesive composition. Within this range, the curing catalyst may help promote improved heat resistance, flowability, and connection performance, without inducing a substantially rapid reaction of the epoxy resin.

Silane Coupling Agent

The adhesive composition may further include a silane coupling agent. The silane coupling agent may function as an adhesion promoter and thus may help enhance adhesion between the surface of an inorganic material, such as a filler, and organic materials via chemical coupling therebetween during blending of the composition.

A suitable silane coupling agent may be used in the composition, and examples thereof may include: epoxy group-containing silane coupling agents, such as 2-(3,4-epoxycyclohexyl)-ethyltrimethoxysilane, 3-glycidoxytrimethoxysilane, 3-glycidoxypropyltriethoxysilane, and the like; amine group-containing silane coupling agents, such as N-2-(aminoethyl)-3-aminopropylmethyldimethoxysilane, N-2-(aminoethyl)-3-aminopropyltrimethoxysilane, N-2-(aminoethyl)-3-aminopropyltriethoxysilane, 3-aminopropyltrimethoxysilane, 3-aminopropyltriethoxysilane, 3-triethoxysilyl-N-(1,3-dimethylbutylidene)propylamine, and N-phenyl-3-aminopropyltrimethoxysilane, and the like; mercapto-containing silane coupling agents, such as 3-mercaptopropylmethyldimethoxysilane, 3-mercaptopropyltriethoxysilane, and the like; and isocyanate-containing silane coupling agents, such as 3-isocyanatepropyltriethoxysilane and the like. These silane coupling agents may be used alone or as mixtures thereof.

The silane coupling agent may be present in an amount of about 0.14 wt % to about 5 wt %, for example about 0.2 wt % to about 3 wt %, or about 0.5 wt % to about 2 wt %, based on the total solid content of the adhesive composition. Within this range, improved adhesion reliability may be obtained and the occurrence of bubbles may be reduced.

Filler

The adhesive composition may further include a filler. Examples of a filler for use in the composition may include: metal powders, such as gold, silver, copper, nickel powders, and the like; and a material derived from metals and/or non-metals, such as alumina, aluminum hydroxide, magnesium hydroxide, calcium carbonate, magnesium carbonate, calcium silicate, magnesium silicate, calcium oxide, magnesium oxide, aluminum oxide, aluminum nitride, silica, boron nitride, titanium dioxide, glass, iron oxide, ceramics, and the like. For example, silica may be used.

The filler may have a suitable the shape and size. For example, spherical silica or amorphous silica may be used as the filler. The particle size of the filler, e.g., silica, may range from about 5 nm to about 20 μm.

The filler may be present in an amount of about 1 wt % to about 30 wt %, for example about 5 wt % to about 25 wt %, based on the total solid content of the adhesive composition. Within this range, flowability, film-forming properties, and adhesion may be improved.

Solvent

The adhesive composition may further include a solvent. The solvent may serve to reduce the viscosity of the adhesive composition, and thereby may facilitate formation of an adhesive film. Examples of solvents for use in the adhesive composition may include organic solvents such as toluene, xylene, propylene glycol monomethyl ether acetate, benzene, acetone, methylethylketone, tetrahydrofuran, dimethylformamide, cyclohexanone, and the like.

According to an embodiment, an adhesive film may include the adhesive composition. There may be no need for a special apparatus or equipment to form an adhesive film using the adhesive composition, and a suitable method may be used to manufacture the adhesive film. For example, the respective components may be dissolved in a solvent, and suitably kneaded using a bead-mill, followed by depositing the resultant on a polyethylene terephthalate (PET) film subjected to release treatment, and drying in an oven at about 100° C. for about 10 to about 30 minutes to prepare an adhesive film having a suitable thickness.

In an embodiment, the adhesive film may include a base film, an adhesive layer, a bonding layer, and a protective film, which may be sequentially stacked in this order.

The adhesive film may have a thickness of about 5 μm to about 200 μm, for example from about 7 μm to about 100 μm. Within this range, the adhesive film may exhibit improved adhesion while providing improved economic feasibility. In an implementation, the adhesive film may have a thickness of about 10 μm to about 60 μm.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES AND COMPARATIVE EXAMPLES

### Examples 1-3

In a 1 L cylindrical flask, a solvent (butanone) was added to and mixed with a polymer resin, an epoxy resin, a phenolic curing resin, an amine curing resin, a curing catalyst, fillers, and a silane coupling agent according to the amounts listed in Table 1, followed by mixing and stirring using a stirrer at 5,000 rpm for 30 minutes, thereby preparing an adhesive composition. Then, the prepared composition was filtered through a 30 μm capsule filter and coated to a thickness of 20 μm using an applicator to prepare an adhesive film, which in turn was dried at 100° C. for 20 minutes and left at room temperature for 1 day, thereby preparing each of adhesive films of Examples 1-3.

### Comparative Examples 1-5

Adhesive compositions were prepared in the same manner as in Examples 1 to 3, except that the components were included in the amounts listed in Table 1.

Respective components used in the examples and the comparative examples were as follows:

TABLE 1

| | Example | | | Comparative Example | | | | |
|---|---|---|---|---|---|---|---|---|
| | 1 | 2 | 3 | 1 | 2 | 3 | 4 | 5 |
| 1 | 61.6 | 68 | 75 | 68 | 68 | 83 | 36.8 | 36.8 |
| 2 | 18 | 13.5 | 8.6 | 14.5 | 13.2 | 3 | 36 | 20 |
| 3 | 3.6 | 3.1 | 2.2 | 6.5 | — | 1.3 | 9.3 | 5 |
| 4 | 5.6 | 4.2 | 3 | — | 7.6 | 1.5 | 6.7 | 3 |
| 5 | 0.2 | 0.2 | 0.2 | — | 0.2 | 0.2 | 0.2 | 0.2 |
| 6 | 10 | 10 | 10 | 10 | 10 | 10 | 10 | — |
| 7 | — | — | — | — | — | — | — | 34 |
| 8 | 1 | 1 | 1 | 1 | 1 | 1 | 1 | 1 |
| Total | 100 | 100 | 100 | 100 | 100 | 100 | 100 | 100 |
| (wt %) | | | | | | | | |

(1) Polymer resin: SG-P3 (weight average molecular weight: 850,000, Tg: 15° C., Nagase Chemtex Co., Ltd.)
(2) Cresol novolac epoxy resin: YDCN-500-90P (EEW: 200 g/eq., S.P.: 90° C., Kukdo Chemical Co., Ltd.)
(3) Aromatic amine curing agent: 4,4′-methylenebis (2,6-diethylaniline) (M.P.: 89° C., Tokyo Chemical Industry Co., Ltd.)
(4) Phenolic curing resin: MEH-7800M (OH eq 175 g/eq., S.P.: 89° C., Meiwa Plastic Co., Ltd.)
(5) Imidazole curing catalyst: 2PZ-CN (Shikoku chemicals Co., Ltd.)
(6) Filler: Aerosil-200 (particle size: 16 nm, Degussa GmbH)
(7) Filler: SO-25H (particle size: 0.5 μm, ADMATECH Co., Ltd.)
(8) Silane coupling agent: KBM-403 (Shinetsu Co., Ltd.)

Each of the adhesive films prepared in Examples 1 to 3 and Comparative Examples 1 to 5 was tested as follows and results are shown in Table 4.

1. Measurement of post-curing storage modulus: 10 sheets of adhesive films were laminated at 60° C. and cut to a size of 5.5 mm×15 mm. The sample had a thickness of about 200 to about 300 μm. The sample was subjected to curing under conditions of wire bonding at 150° C. for 20 minutes. Then, the storage modulus at 150° C. of the sample was measured using a DMA (Dynamic Mechanical Analyzer, Model Q800, TA Co., Ltd.) by scanning from 30° C. to 260° C. at a temperature increasing rate of 4° C./min.

2. Measurement of pre-curing heat quantity and post-curing heat quantity: The pre-curing heat quantity of each of the adhesive films was measured using a DSC (Differential Scanning calorimeter, TA Co., Ltd.) by scanning from 0° C. to 300° C. at a temperature increasing rate of 10° C./min. The post-curing heat quantity of the adhesive film was measured after curing the film under conditions of wire bonding at 150° C. for 20 minutes.

3. Reaction curing rate: To simulate thermal exposure upon wire bonding, the prepared adhesive film was cured on a hot plate at 150° C. for 20 minutes, and the curing heat quantity of the adhesive film was measured. Then, the curing reaction rate of the adhesive film was calculated using the post-curing heat quantity and the pre-curing heat quantity of Item 2 according to the following equation.

Reaction curing rate (%)=(1-(post curing heat quantity)/(pre-curing heat quantity))×100%

4. Post-molding void area ratio: A polished wafer was placed on a hot plate of a mounter and subjected to removal of foreign matter using isopropyl alcohol (IPA), and a mirror plane of the wafer was placed on an adhesive surface of the prepared adhesive film. Here, the mounter temperature was set to 60° C., which is a general surface temperature. The wafer-adhesive film assembly was cut to a chip size of 10×10 mm by sawing, and attached at 120° C. and 1 kgf /1 sec to a PCB, which had been subjected to pre-treatment under the conditions set forth in Table 2, thereby preparing a sample.

TABLE 2

PCB: 62 mm one shot PCB
PCB baking: in an oven at 120□ for 1 hour
Plasma treatment after baking

Then, the prepared sample was subjected to 1 cycle of curing on a hot plate at 150° C. for 20 minutes and EMC molding was performed under the conditions set forth in Table 3.

TABLE 3
EMC Tablet: Cheil Industries EMC SG-8500BC

| Mold | Clamp | Transfer | Transfer | Curing |
|---|---|---|---|---|
| temperature | pressure | pressure | time | time |
| 175□ | 30 ton | 1.1 ton | 18 sec | 60 sec |

Then, the resultant was divided into respective units using a circular saw, followed by removal of PCB and grinding using a grinder until the adhesive layer of the adhesive film was exposed for measurement of the void proportion after molding. Here, in order to facilitate void observation, the resultant was ground such that a solder resist layer of the PCB partially remained to the point of being semi-transparent.

After grinding, the exposed adhesive layer was photographed using a microscope (magnification: 25×) and the presence of voids was inspected through image analysis. To digitize/measure the number of voids, a lattice counting method was used. Specifically, the total area of the sample was divided into 10 lattice rows and 10 lattice columns, and the number of lattices including voids was counted and converted into % (void area ratio).

Void area ratio=(void area/total area)×100%

5. Reflow resistance: Each of the prepared adhesive films was mounted on a 80 μm thick wafer coated with a dioxide layer and cut into chips having a size 10×10 mm. The chips were attached at 120° C. to a QDP package. The resulting package was left on a hot plate for 20 minutes under conditions of wire bonding and molded with an EMC (SG-8500BC, Cheil Industries, Korea) at 175° C. for 120 seconds, followed by post-curing in an oven at 175° C. for 2 hours. The prepared specimen was allowed to absorb moisture at 85° C./85RH% for 168 hours, and reflow was conducted three times at a maximum temperature of 260° C. Then, cracks were observed on the specimen.

TABLE 4

| | | Example | | | Comparative Example | | | | |
|---|---|---|---|---|---|---|---|---|---|
| | | 1 | 2 | 3 | 1 | 2 | 3 | 4 | 5 |
| Storage | After curing | 3.12 | 2.87 | 2.52 | 1.574 | 1.378 | 1.694 | 3.82 | 2.8 |
| modulus | at 150° C. for | | | | | | | | |
| (DMA), | 20 minutes | | | | | | | | |
| MPa at | | | | | | | | | |
| 150° C. | | | | | | | | | |
| DSC heat | Before curing | 34.2 | 27.6 | 24.1 | 19.3 | 21.4 | 13.5 | 68.7 | 32.4 |
| quantity | After curing | 10.9 | 10.8 | 11.3 | 14.5 | 19 | 5.8 | 19.9 | 12.3 |
| | at 150° C. for | | | | | | | | |
| | 20 minutes | | | | | | | | |
| Curing | After curing | 68 | 61 | 53 | 25 | 11 | 57 | 71 | 62 |
| rate (%) | at 150° C. for | | | | | | | | |
| | 20 minutes | | | | | | | | |

| | | | | | | | | |
|---|---|---|---|---|---|---|---|---|
| Post-molding void area | 4 | 4 | 1 | 2 | 4 | 2 | 29 | 17 |
| ratio (%) | | | | | | | | |
| Reflow resistance (crack | 0 | 0 | 0 | 70 | 40 | 10 | 70 | 60 |
| (%)) | | | | | | | | |

For the adhesive films prepared in Examples 1 to 3, the phenolic curing agent was included with an epoxy resin and an amine curing agent, and thus the adhesive film was provided with an improved crosslinking system through acid promotion of the OH functional group of the phenolic curing agent (even with a reduced thermal exposure of wire bonding at 150° C. for 20 minutes), thereby substantially preventing reliability deterioration resulting from failure and insufficient adhesion (e.g., caused by foaming of the composition due to insufficient curing). As illustrated above in Table 4, the rapid reaction of the adhesive films of Examples 1 to 3 provided a storage modulus of 2 MPa or more and a curing rate of 50% or more even after curing at 150° C. for 20 minutes.

For the single curing system of the amine curing agent of Comparative Example 1 and the single curing system of the phenolic curing agent of Comparative Example 2, the reduced thermal exposure of 150° C. for 20 minutes resulted in an insufficient crosslinking structure, which led to low curing rate and storage modulus, thereby causing undesirable cracking in the reflow resistance test.

For the adhesive films prepared in Comparative Examples 3 to 5, the post-curing storage modulus was relatively increased due to rapid reaction. However, the relatively low amounts of the polymer resin (i.e., thermoplastic resin) of the adhesive films resulted in low void removal characteristics (when removing voids trapped in a PCB in the die-attach process by applying pressure to the voids upon EMC molding), thereby causing undesirable cracking in the reflow resistance test.

By way of summary and review, silver pastes may be used to attach semiconductor devices to each other or to a support member. The support member may be required to have a relatively small size and a relatively compact configuration, i.e., due to an increasing trend of size reduction and high capacity semiconductor devices. Silver pastes may have problems, such as wire bonding failure, caused by, e.g., protuberances or sloping of a semiconductor device, generation of bubbles/voids, difficulty in thickness control, and the like.

In an attempt to avoid the problems associate with a silver paste, an adhesive film may be used in the assembly of a semiconductor, e.g., by being used together with a dicing film, which refers to a film for holding a semiconductor wafer for dicing in one or more (e.g., a series) of semiconductor chip manufacturing processes. Dicing may be a process of cutting the semiconductor wafer into individual chips, followed by an expanding process, a pick-up process, and the like.

Upon dicing, a PET cover film removed from a dicing film may be stacked on an adhesive film to form a single film as an adhesive for semiconductor assembly, and a semiconductor wafer may be placed on the film, followed by sawing using, e.g., a circular diamond blade. A laser beam may be radiated to a semiconductor wafer to selectively cut an inner portion of the semiconductor wafer, followed by expanding the film and cutting the wafer together with the adhesive film, thereby providing individualized semiconductor chips.

In a semiconductor assembly process using a dicing die-bonding adhesive film for semiconductor assembly, the adhesive film may be mounted together with the dicing film on the semiconductor wafer having a circuit thereon at about 50 to about 80° C., followed by dicing the semiconductor wafer into individual chips, which in turn may be stacked one above another at high temperature through a die-attach process.

Since a circuit board used for manufacture of the semiconductor device may have an irregular surface, e.g., due to wiring, the adhesive layer may be expected to exhibit flowability in order to reduce the size of initial voids generated when the semiconductor chips are stacked on the circuit board by the die-attach process (which may be performed at a relatively high temperature). At this time, it may be desireable to remove these voids under relatively high temperature and relatively high pressure conditions in an epoxy molding process after stacking of the semiconductor wafer. The voids remaining after the molding process may cause reliability deterioration.

In order to hold the chips stacked on the film, the film may be subjected to pre-curing or semi-curing at about 125 to about 170° C. for a predetermined period of time, followed by epoxy molding, and post-mold curing at about 175° C. for about 1 to about 2 hours to cure the molded EMC resin and the adhesive film. Semi-curing may be performed at about 125 to about 170° C. for about 40 to about 70 minutes to semi-cure the adhesive film. As the number of semiconductor diodes increases, e.g., due to high integration of semiconductor diodes, a time for semiconductor assembly may increases, thereby lowering productivity.

The above mentioned problems of lowered productivity and reliability deterioration may be substantially prevented by using the adhesive composition/film according to the embodiments described in this disclosure. The adhesive film may include about 60 to about 80 percent by weight (wt %) of a thermoplastic resin based on the total solid content, a phenolic curing agent, and an amine curing agent, and may have a storage modulus of about 2 MPa or more and a reaction curing rate of about 50% or more when cured at 150° C. for 20 minutes. The adhesive film may substantially prevent reliability deterioration resulting from failure and insufficient adhesion (e.g., caused by foaming of the composition due to insufficient curing), and may have rapid reaction even after curing at 150° C. for 20 minutes

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An adhesive film for a semiconductor, the adhesive film comprising:
about 60 wt % to about 80 wt % of a thermoplastic resin based on a total solid content of the adhesive film;
a phenolic curing agent; and
an amine curing agent, the adhesive film having a storage modulus of about 2 MPa or more and a reaction curing rate of about 50% or more when cured at 150° C. for 20 minutes.

2. The adhesive film as claimed in claim 1, wherein the adhesive film has a void area ratio of about 10% or less when cured at 150° C. for 20 minutes and molded at 175° C. for 120 seconds.

3. The adhesive film as claimed in claim 1, wherein the amine curing agent includes at least two amine groups.

4. The adhesive film as claimed in claim 1, wherein the amine curing agent includes a compound represented by one of Formulae 1 to 5: 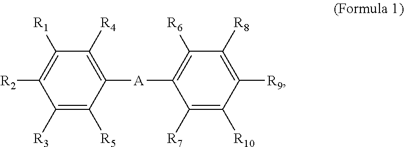
wherein, in Formula 1,
A is a single bond or is selected from the group of —CH₂—, —CH₂CH₂—, —SO₂—, —NHCO—, —C(CH₃)₂—, and —O—, and
R₁ to R₁₀ are each independently selected from the group of hydrogen, a C₁-C₄ alkyl group, a C₁-C₄ alkoxy group, and an amine group, with the proviso that at least one of R₁ to R₁₀ is an amine group, 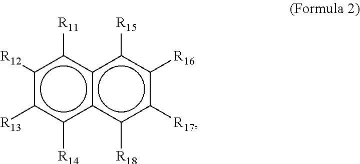
wherein, in Formula 2,
R₁₁ to R₁₈ are each independently selected from the group of hydrogen, a C₁ to C₄ alkyl group, an alkoxy group, a hydroxyl group, a cyanide group, a halogen, and an amine group, with the proviso that at least one of R₁₁ to R₁₈ is an amine group, 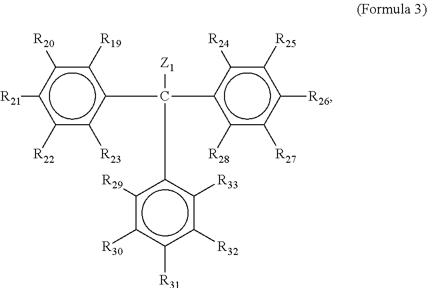
wherein, in Formula 3,
Z₁ is selected from the group of hydrogen, a C₁ to C₄ alkyl group, an alkoxy group, and a hydroxyl group, and
R₁₉ to R₃₃ are each independently selected from the group of hydrogen, a C₁ to C₄ alkyl group, an alkoxy group, a hydroxyl group, a cyanide group, a halogen, and an amine group, with the proviso that at least one of R₁₉ to R₃₃ is an amine group, 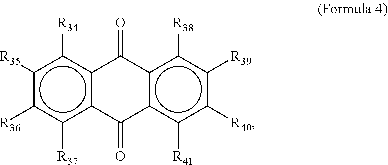
wherein, in Formula 4,
R₃₄ to R₄₁ are each independently selected from the group of hydrogen, a C₁ to C₄ alkyl group, an alkoxy group, a hydroxyl group, a cyanide group, a halogen, and an amine group, with the proviso that at least one of R₃₄ to R₄₁ is an amine group, 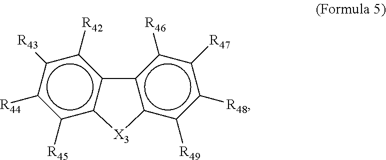
wherein, in Formula 5,
X₃ is selected from the group of —CH₂—, —NH—, —SO₂—, —S—, and —O—, and
R₄₂ to R₄₉ are each independently selected from the group of hydrogen, a C₁ to C₄ alkyl group, an alkoxy group, a hydroxyl group, a cyanide group, a halogen, and an amine group, with the proviso that at least one of R₄₂ to R₄₉ is an amine group.

5. The adhesive film as claimed in claim 4, wherein:
the amine curing agent includes the compound represented by Formula 1,
at least one of R₁ to R₃ is an amine group, and
at least one of R₈ to R₁₀ is an amine group.

6. The adhesive film as claimed in claim 5, wherein R₂ and R₉ are each an amine group.

7. The adhesive film as claimed in claim 1, wherein the thermoplastic resin has a weight average molecular weight of about 50,000 g/mol to about 5,000,000 g/mol.

8. The adhesive film as claimed in claim 1, further comprising about 5 wt % to about 30 wt % of an epoxy resin, wherein:
the thermoplastic resin is an epoxy group containing thermoplastic resin, and the epoxy resin and the thermoplastic resin are different.

9. The adhesive film as claimed in claim 1, wherein a weight ratio of the phenolic curing agent to the amine curing agent ranges from about 3:1 to about 1:11.

10. The adhesive film as claimed in claim 1, further comprising a curing catalyst.

11. The adhesive film as claimed in claim 10, wherein the curing catalyst has a melting point of about 100° C. to about 160° C.

12. The adhesive film as claimed in claim 10, wherein the curing catalyst includes at least one selected from the group of a melamine catalyst, an imidazole catalyst, and a phosphorous catalyst.

13. The adhesive film as claimed in claim 1, further comprising a silane coupling agent.

14. An adhesive composition for a semiconductor, the adhesive composition comprising:
about 60 wt % to about 80 wt % of a thermoplastic resin;
about 5 wt % to about 30 wt % of an epoxy resin;
about 0.5 wt % to about 14 wt % of a phenolic curing agent;
about 1 wt % to about 10 wt % of an aromatic diamine curing agent;
about 0.1 wt % to about 10 wt % of a curing catalyst;
about 0.14 wt % to about 5 wt % of a silane coupling agent; and
about 1 wt % to about 30 wt % of a filler, based on a total amount of the adhesive composition in terms of solid content.

15. The adhesive composition as claimed in claim 14, wherein the adhesive composition has a storage modulus of about 2 MPa or more and a reaction curing rate of about 50% or more when cured at 150° C. for 20 minutes.

16. A method of manufacturing a semiconductor device, the method comprising:
attaching a first chip to a substrate using an adhesive film;
wire bonding the first chip to the substrate; and
epoxy-mold curing the wire bonded first chip and substrate,
wherein:
the adhesive film includes:
about 60 wt % to about 80 wt % of a thermoplastic resin based on a total solid content of the adhesive film,
a phenolic curing agent, and
an amine curing agent, and
the adhesive film has a storage modulus of about 2 MPa or more and a reaction curing rate of about 50% or more when cured at 150° C. for 20 minutes.

17. The method as claimed in claim 16, wherein the substrate is a wiring substrate or a second chip.

18. The method as claimed in claim 16, wherein the wire bonding is successively performed after attaching the first chip to the substrate.

19. The method as claimed in claim 16, wherein the adhesive film is completely cured during the epoxy-mold curing.

20. The method as claimed in claim 16, wherein:
attaching the first chip to the substrate is performed at about 100° C. to about 150° C. for about 1 minute to about 10 minutes,
wire bonding the first chip to the substrate is performed at about 140° C. to about 160° C. for about 10 minutes to about 30 minutes, and
epoxy-mold curing the wire bonded first chip and substrate is performed at about 170° C. to about 180° C. for less than about 5 minutes.
